(19) United States
(12) Patent Application Publication
(10) Pub. No.: US 2006/0231395 A1
(43) Pub. Date: Oct. 19, 2006

(54) Control for an excimer emitter

(75) Inventors: Andreas Ihme, Goldbach (DE); Reiner Mehnert, Markkleeberg (DE); Michael Reising, Offenbach (DE)

Correspondence Address: LEYDIG VOIT & MAYER, LTD, TWO PRUDENTIAL PLAZA, SUITE 4900, 180 NORTH STETSON AVENUE, CHICAGO, IL, 60601-6780, US

(73) Assignee: MAN ROLAND DRUCKMASCHINEN AG, Offenbach (DE)

(21) Appl. No.: 10/559,506

(22) PCT Filed: May 8, 2004
(86) PCT No.: PCT/EP04/04934

§ 371 Date: Apr. 11, 2006

(30) Foreign Application Priority Data
Jun. 5, 2003 (DE) 103 25 771.3

(51) Int. Cl. C25B 13/00; C25B 9/00; C23C 14/00; C25B 11/00; C23C 14/32

(52) U.S. Cl. 204/298.34; 204/192.35

(57) ABSTRACT

A control for an excimer emitter, particularly for the dryer in a printing press, comprises an HF generator that is connected on the output side to an excimer emitter. To enable a higher UV intensity of radiation, the HF generator (1) is provided in the form of a tube-type generator with a feedback: the output of this HF generator (1) is connected to the input of a working circuit (3) comprising a capacitor (C) and an inductive resistor (L), and; the excimer emitter (5) is connected to the output of the working circuit (3).

### FIELD OF THE INVENTION

The invention concerns a control for an excimer emitter.

### BACKGROUND OF THE INVENTION

UV driers are used both in sheet-fed and web-fed printing presses. Traditional UV driers are designed as mercury discharge lamps. The disadvantage with such UV driers is that with these broad-band radiating lamps, a relatively large amount of ozone is formed, which must be suctioned off and conducted to the outside. Special UV lamps for driers are excimer emitters, which emit a monochromatic UV radiation. In actual practice, emitters are frequently used here, which emit a wavelength of 308 nm. An advantage of such an emitter is that a heating of the paper does not take place, since the radiation does not contain any IR fractions. With a wavelength of 308 nm, ozone formation does not take place either. There is also a better utilization of the electrical input power for the drying process.

An excimer emitter essentially consists of a coaxially built capacitor, between whose electrodes, there is a gas mixture, which can be ignited by an electrical discharge. Such a gas mixture is, for example, xenon, a chlorine compound, and argon as the carrier gas. During the gas discharge, molecules XeCl*, which are excited for a short term, are hereby formed. These excited molecules emit a wavelength of 308 nm.

The coaxial walls of the gas space are formed by quartz tubes, on which interior or exterior electrodes are placed. Provision may hereby be made so that the interior and another exterior tube respectively receive a throughflow of cooling water.

To excite the short-lived molecules, a barrier discharge in the gas space and in the dielectric quartz is required. This takes place by means of HF voltages with amplitudes of 2 to 10 kV and frequencies of 100 to 1000 kHz. If the high voltage, which is applied on the discharge screws, exceeds the breakdown voltage of the gas, a discharge current, which produces excimer molecules and causes light emission, flows. The current flow, however, is interrupted after a very short time (nanoseconds), because the dielectric quartz is charged. That leads to a momentary reduction of the electrical field strength in the discharge gap and interrupts the current flow. To produce the required HF voltages, HF generators are used with known excimer emitters, which have end stages with ferrite transformers. It is precisely the transmission characteristics of the ferrite material which limits both the frequency and the HF output of such generators. In order to use excimer emitters in high-speed sheet-fed offset printers, illumination strengths are required at the level of the stock of more than 300 mW/cm². Such high-output excimer emitters in the range of wavelength 308 nm are not available, however, with ferrite transformers. From DE 42 38 388 C2, an electronic circuit arrangement for the control of an excimer emitter by means of a high-voltage transmitter is known.

### SUMMARY OF THE INVENTION

The object of the invention under consideration is to expand a control for an excimer emitter in such a way that a higher UV radiation strength can be attained.

This goal is attained by the control for an excimer emitter of the invention. In accordance with the invention, provision is made so that the control of the excimer emitter takes place by means of a specially adapted HF generator, which is designed as a self-exciting single-circuit generator with a water-cooled transmitting tube and which holds an internal or external working circuit, via which the excimer emitter tube is connected to the generator. The output is coupled into the excimer emitter via water-cooled capacitors and resonant-circuit inductances.

In accordance with the preferred embodiment of the invention, the working circuit connecting the HF generator to the excimer emitter is constructed so that it is located externally and shielded electrically. This externally located and electrically shielded working circuit is then connected to the HF generator via an HF cable. The working circuit itself is thereby in the vicinity of the excimer emitter. This arrangement makes it possible to connect several excimer emitters to the working circuit.

Another development of the invention consists of integrating the transmitting tubes into the unit which holds the working circuit. Thus, it is also possible to provide power to several excimer emitters located in one printing unit or another device of the printing press from one working circuit.

An advantageous development of the invention provides for the inductive resistor in the working circuit, via which the HF generator is connected to the excimer emitter, to be constructed in an adjustable or changeable manner, so that the discharge characteristics of the excimer emitter can be adapted correctly for the entire output range and thus an optimal coupling of the HF output into the barrier discharge of the emitter can be attained. Provision can be made hereby to use an adjustable inductive resistor. Alternatively, it is also possible to use an inductive resistor with several tap possibilities. What is used then is the inductive resistor which produces the best discharging characteristics.

The explanation of an embodiment example of the invention is set forth below with the aid of the drawing.

Another development of the invention consists of also integrating the transmitting tubes into the unit which holds the working circuit. Thus, it is also possible to provision several excimer emitters located in one printing unit or another device of the printing press from one working circuit.

An advantageous development of the invention provides for the inductive resistor in the working circuit, via which the HF generator is connected to the excimer emitter, to be constructed in an adjustable or changeable manner, so that the discharge characteristics of the excimer emitter can be adapted correctly for the entire output range and thus an optimal coupling of the HF output into the barrier discharge of the emitter can be attained. Provision can be made hereby to use an adjustable inductive resistor. Alternatively, it is also possible to use an inductive resistor with several tap possibilities. What is used then is the inductive resistor which produces the best discharging characteristics.

The explanation of an embodiment example of the invention is set forth below with the aid of the drawing.

### BRIEF DESCRIPTION OF THE DRAWING

FIG. 1 shows a generator constructed in accordance with an embodiment of the invention with a working circuit and the excimer emitter connected to it.

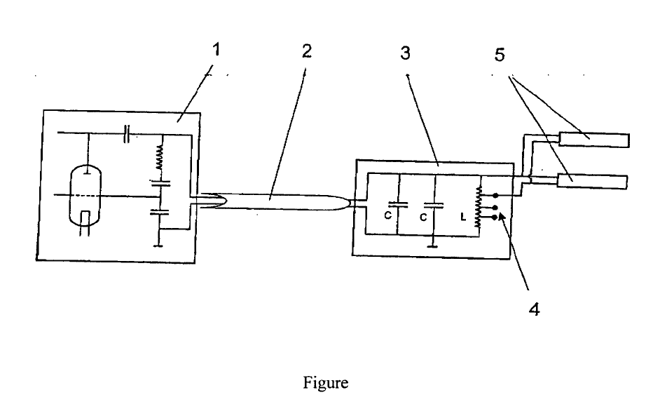

An HF generator 1 is constructed, as shown, as a tube generator with a feedback. The output of this HF generator 1 is connected, via an HF cable 2, with the input of a working circuit 3. This working circuit 3 has two capacitors C and, on the output side, an inductive resistor with several taps 4. Two excimer emitters 5 are connected via a contact of the taps 4, wherein the tap 4 is selected, which delivers the desired inductance value of the working circuit 3. The excimer emitters 5 are designed as transmitting tubes, whose structure is known.

The excimer emitters 5 are located in a printing press (not depicted) and are used for drying of the stock. The working circuit 3 is assigned to the excimer emitters 5—that is, is located in their vicinity. Via the HF cable 2, a distance of a few meters between the HF generator 1 and the working circuit 3 can be bridged over. Thus, it is possible to set up the HF generator next to the printing press.

Furthermore, provision is made so that the capacitance values of the capacitors C in the working circuit 3 are larger than the capacitances of the HF cable L and of the excimer emitter 5 connected to the working circuit 3. Thus, great lengths of the cable 2 can be realized.

1-7. (canceled)

8. A control device for an excimer emitter, comprising:
an HF generator constructed as a tube generator having a feedback;
a working circuit having a capacitor and an inductive resistor, the working circuit having an input connected to an output of the HF generator and an output for connecting to the excimer emitter.

9. A control device as in claim 8, further including an HF cable connecting the input of the working circuit to the output of the HF generator.

10. A control device as in claim 9, wherein the capacitor in the working circuit has a capacitance value greater than a capacitance value of the HF cable and a capacitance value of the excimer emitter connected to the working circuit.

11. A control device as in claim 8, wherein the output of the working circuit is connected to multiple excimer emitters.

12. A control device as in claim 8, wherein the inductive resistor of the working circuit is adjustable.

13. A control device as in claim 8, wherein the inductive resistor of the working circuit has multiple taps with different inductance values selectable for connecting to an excimer emitter.

14. A control device as in claim 8, wherein the working circuit is disposed adjacent the excimer emitter.
